(19) United States
(12) Patent Application Publication
(10) Pub. No.: US 2004/0163595 A1
(43) Pub. Date: Aug. 26, 2004

(54) Plasma processing apparatus

(76) Inventors: Manabu Edamura, Niihari-gun (JP); Go Miya, Niihari-gun (JP); Ken Yoshioka, Hikari-shi (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/372,832

(22) Filed: Feb. 26, 2003

(51) Int. Cl. C23C 16/00

(52) U.S. Cl. 118/723 I

(57) ABSTRACT

In a plasma processing apparatus including an electrode 6 provided within a processing chamber 1, an induction coil 10 and a ring-shaped electrically conductive cover 11 in contact with the induction coil both provided through an insulating material 9 in an upper portion of the processing chamber 1, and a high-frequency power supply 13 to supply power to the induction coil 10, an induced current is generated in the ring-shaped conductor 11 by the induction coil 10 and a plasma is subjected to induction heating by the induced current flowing through the conductor 11. An induction field generated by the induction coil 10 is shielded so that the induction field does not leak to a region in which a plasma is generated. The current which performs the induction heating of the plasma is the current flowing through the ring-shaped conductor 11, and because unlike a usual coil this conductor has no end, complete circumferential uniformity of a plasma is realized.

### BACKGROUND OF THE INVENTION

1. Field of the Invention

The present invention relates to a plasma processing apparatus suitable for providing etching and film deposition processing in the fabrication of semiconductors, liquid crystal display substrates and the like.

2. Description of the Related Art

Along with the miniaturization of semiconductor devices, process conditions (process windows) of the plasma process that provide uniform processes in a wafer area have become tighter year by year, and future plasma processing apparatuses will require a more perfect control of the process condition. In order to realize this aim, it is necessary to create an apparatus capable of controlling conditions such as the distribution of a plasma, the dissociation of a process gas and the surface temperature in the reactor with very high accuracy.

At present, a high-frequency inductively coupled plasma source is available as a plasma source used in these plasma process apparatuses. An inductively coupled plasma processing apparatus is a plasma apparatus by which a plasma is generated and maintained in such a manner that high-frequency power of hundreds of kilohertz to hundreds of megaheltz is supplied to a high-frequency coil typically in the form of a loop, coil or helix disposed outside the processing chamber through an insulating material made of quartz etc., which is part of the chamber, and energy is supplied to a process gas introduced into the processing chamber by accelerating electrons in the plasma in an induction field formed by the coil (for example, refer to the Japanese Patent Laid-Open No. 2-235332).

Furthermore, there is also a high-frequency inductively coupled plasma processing apparatus constructed in such a way that this coil is provided within the chamber. In this plasma processing apparatus, a helical coil which is a high-frequency induction coil is disposed in the chamber in a position opposed to a semiconductor wafer subjected to processing (refer for example to Japanese Patent Laid-Open No. 7-106095).

These plasma processing apparatuses are called the inductively coupled plasma processing apparatus, because an induced current is generated in a plasma and in terms of an electric circuit, the plasma and the high-frequency coil are inductively coupled (a transformer circuit in which the coil is regarded as a primary coil and the current in the plasma is regarded as a secondary coil). Advantages of the inductively coupled plasma processing apparatus are the following. A plasma of relatively high density of 1E11 to 1E12 (cm-3) can be generated under a low pressure of several m torr low-cost construction of a simple coil and a high-frequency power supply, a plasma of large area can be easily generated by arranging the coil two-dimensionally opposed to a workpiece subjected to processing, it is possible to reduce particles flying onto a workpiece during processing because the interior of the processing chamber is simple, and so on. In these apparatuses, the ions have a long mean free path because of the generation of a high-density plasma under a low pressure and the directionality of ions incident on a workpiece is good. Therefore, these apparatuses are suitable for microfabrication and can provide high processing rates.

A semiconductor wafer, which is a workpiece mainly treated in the plasma process, has a circular form and the chamber of a plasma processing apparatus for semiconductor wafers also has a circular horizontal inner section accordingly. For example, in a plasma etching apparatus, a gas is generally introduced from the center or side and exhausted from the bottom. Although it is desirable that the result of wafer etching be completely uniform in a wafer surface area, the phenomena of reactions on a wafer is not completely uniform due to the distribution of a plasma, dissociation species and reaction products. For example, as for reaction products generated from the wafer, it is inevitable that the reaction product concentration is higher in the center portion of the reaction chamber.

In order to compensate for the nonuniformity of etching by this nonuniform concentration, it is necessary to make the result of wafer etching uniform by taking means, such as lowering the plasma concentration on the periphery to a level lower than the concentration in the center or lowering the wafer temperature in the peripheral portion to a level lower than the temperature in the center portion.

On the other hand, nonuniformity may sometimes occur in the azimuthal direction of a wafer due to the nonuniformity in gas flow and plasma generation. However, this nonuniformity can be solved unlike the nonuniformity in the radial direction of the wafer. The gas flow can be made almost uniform in the azimuthal direction by optimizing the exhaust structure in the bottom. In an inductively coupled plasma processing apparatus, azimuthal nonuniformity ascribable to the construction of the apparatus occurs.

That is, as described in a paper by Richard S. Wise et al., a coil always has an end which is connected to the high-frequency power supply side and an end which is connected to the installation side, so nonuniformity in the azimuthal direction of a plasma ascribable to the construction of the coil occurs. Furthermore, in a region of low density, electrons are directly accelerated by a voltage applied to the coil and the effect of a plasma generated in a manner of capacitive coupling cannot be ignored. Because the voltage applied to the coil is not constant, this plasma generated in a manner of capacitive coupling is generated in a large amount in places where the voltage is high and hence circumferential nonuniformity occurs (for example, refer to Appl. Phys. Lett. 68, 2499 (1996): Richard S. Wise).

In order to solve these problems, for example, there has been proposed a structure in which a plurality of coils which are quite identical are provided side by side at intervals of a specific angle (refer for example to U.S. Pat. No. 5,753,044). Especially in U.S. Pat. No. 5,753,044, coils of three systems are provided at intervals of 120 degrees. However, when such a structure is adopted, the number of coils increases and power supply to the coils is performed only from the center, increasing constraints in terms of apparatus design.

### SUMMARY OF THE INVENTION

It is an the object of the present invention to provide a plasma processing apparatus which generates a plasma in an arbitrary place and generates a stable plasma with a high efficiency under wider conditions by solving the problem of azimuthal nonuniformity of a plasma peculiar to the prior art as described above.

The above-described problem can be solved by a constitution as described below. For example, a conductor in ring form is provided in contact with an induction coil, and first an induced current in place of a plasma is caused to flow through this conductor. Next, a plasma is subjected to induction heating by the induced current flowing through the ring-shaped conductor. An induction field generated by the induction coil is shielded so that it does not leak to a region where a plasma is generated. That is, although in a usual apparatus a plasma is generated by an inductive coupling with an induction coil serving as a primary coil and the plasma serving as a secondary coil, in the present invention a plasma is generated with the induction coil serving as a primary coil, the ring-shaped conductor serving as a secondary coil and the plasma serving as a tertiary coil. The current which performs the induction heating of the plasma is the current flowing through the ring-shaped conductor, and because unlike a usual coil this conductor has no end, complete circumferential uniformity of a plasma is realized.

The ring-shaped conductor provided in the above-described coil so as to provide an inductive coupling is an electrically conductive member in circular form, ring form or in the form of a shape which can be roughly regarded as these forms.

### BRIEF DESCRIPTION OF THE DRAWINGS

FIG. 1 is a drawing explaining the structure of a plasma processing apparatus related to an embodiment of the invention;

FIG. 2 is a drawing explaining the shape of an induction coil used in an embodiment of the invention;

FIG. 3 is a drawing explaining an example of variation of the shape of an induction coil used in an embodiment of the invention;

FIG. 4 is a drawing explaining the relationship between the slit and induction field of the induction coil shown in FIG. 4;

FIG. 5 is a drawing explaining the structure of a plasma processing apparatus related to an embodiment of the invention;

FIG. 6 is a drawing explaining the structure of a plasma processing apparatus related to an embodiment of the invention;

FIG. 7 is a drawing explaining the shape of a Faraday shield used in the invention;

FIG. 8 is a drawing explaining the structure of a plasma processing apparatus related to an embodiment of the invention;

FIG. 9 is a drawing explaining the structure of a plasma processing apparatus related to an embodiment of the invention; and

FIG. 10 is a drawing explaining the shape of a flat-plate-like electric conductor.

### DETAILED DESCRIPTION OF THE PREFERRED EMBODIMENTS

Although the present invention is not limited to the field of the fabrication of semiconductors and can be applied also to the manufacturing of liquid crystal displays and the film deposition and surface processing of various materials, embodiments will be described here by taking as an example a plasma etching apparatus used for fabricating semiconductor devices.

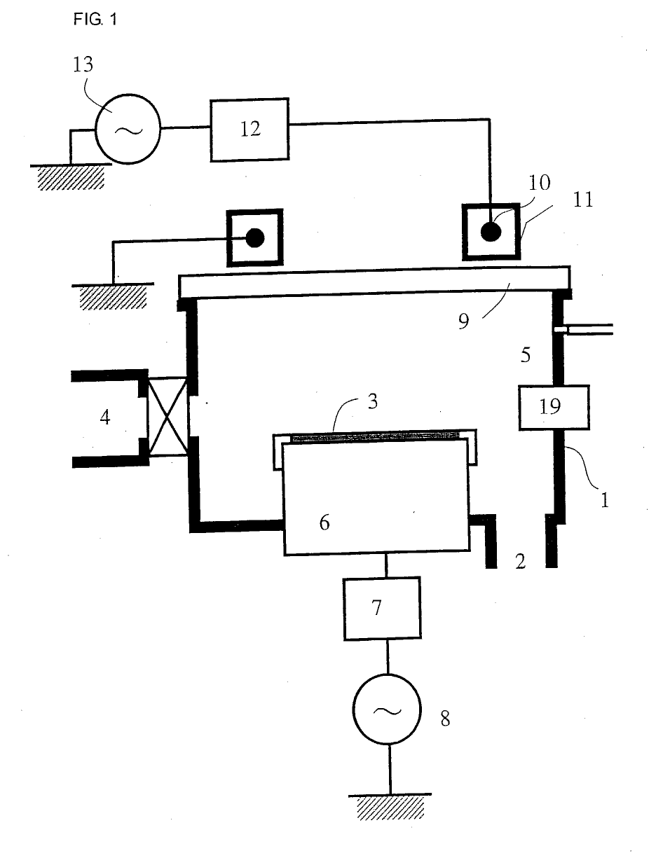

FIG. 1 shows an embodiment of the invention. A processing chamber 1 in the figure is, for example, a vacuum vessel which is made of aluminum or stainless steel and the surface of which is treated with alumite (anodized aluminum), and this vacuum vessel is electrically grounded. The processing chamber 1 is provided with vacuum evacuation means 2 and a transfer system 4 for sending into and out of the chamber 1 a semiconductor wafer 3 to be subjected to processing. In the processing chamber 1 is provided an electrode 6 on which the semiconductor wafer 3 is placed. A wafer carried into the processing chamber by the transfer system 4 is transferred onto the electrode and is supported by the electrode 6. A high-frequency power supply 8 is connected to the electrode 6 through an impedance matching circuit 7 in order to control the energy of ions which are incident on the semiconductor wafer 3 during plasma processing. A gas for etching is introduced from an introduction port 5 into the chamber.

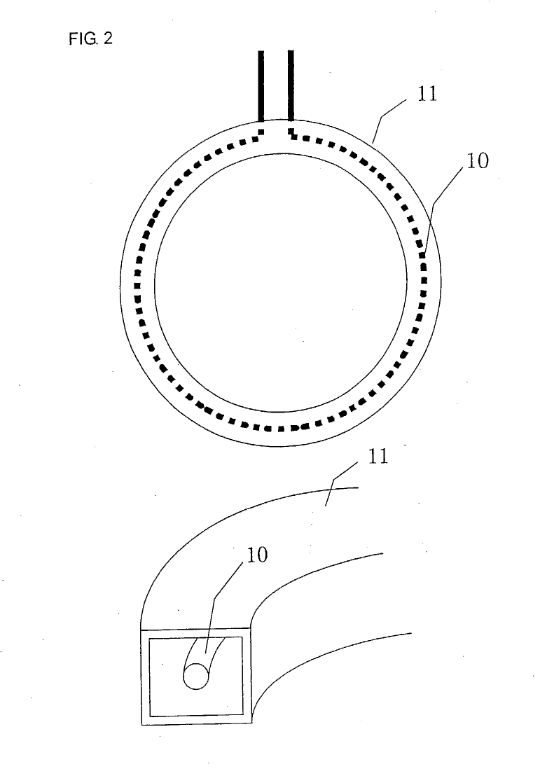

In a position opposed to the wafer is provided a high-frequency induction coil 10 through an insulating material 9 made of quartz, alumina, ceramics, etc. on atmospheric side, i.e., on a side opposite to the wafer. The high-frequency induction coil 10 is covered with a ring-shaped electrically conductive cover 11 of the construction shown in FIG. 2 so as to cover the high-frequency induction coil. The electrically conductive cover is electrically insulated from the induction coil and a high-frequency current flows through the electrically conductive cover so as to interfere with an induction field of the high-frequency induction coil, i.e., in a reverse direction. In order to reduce heat generation losses, a low electric resistance material such as copper is used in the surface of this electrically conductive cover. Furthermore, this electrically conductive cover may be formed as a two-layer structure with a magnetic material to ensure the magnetic field shield effect.

Power is supplied to the high-frequency induction coil 10 through the matching device 12 from a high-frequency power supply 13.

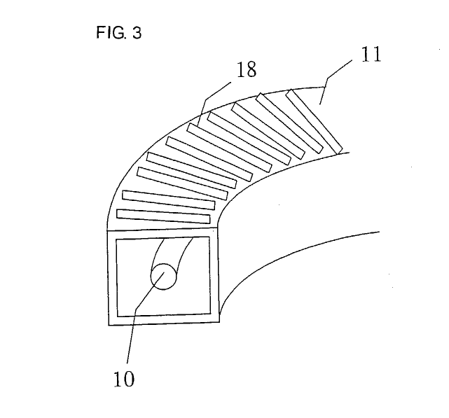

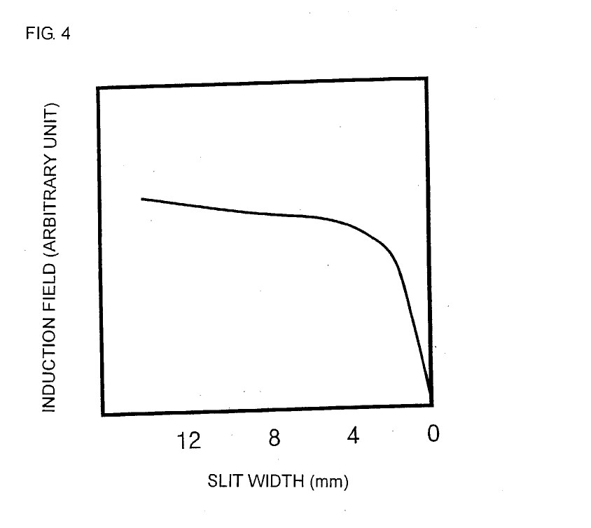

Furthermore, as shown in FIG. 3, in order to define a portion through which an induced current flows, it is effective to install slits 18 in portions so that the slits cross the portions where the current should not flow. When the width of a slit is large at this time, the induction field leaks to the outside. As is apparent from the relationship between slit width and induction field intensity shown in FIG. 4, the induction field which leaks to the outside can be reduced by narrowing the width of a slit. Therefore, as is apparent from FIG. 4, it is desirable that the slit width is less than 2 mm.

The current induced into the electric conductor then generates and maintains a plasma by providing an inductive coupling with the plasma. It is known that in an inductively coupled plasma apparatus, a plasma is generated during ignition and at a low density in a manner of capacitive coupling due to a high voltage generated in the induction coil. With an arrangement as shown in FIG. 1, the voltage generated in the coil is not very high, posing the problem that as a result the plasma does not ignites. For this reason, in the embodiment shown in FIG. 1, there is provided another plasma source 19 to ignite the plasma and raise the plasma density to a certain degree.

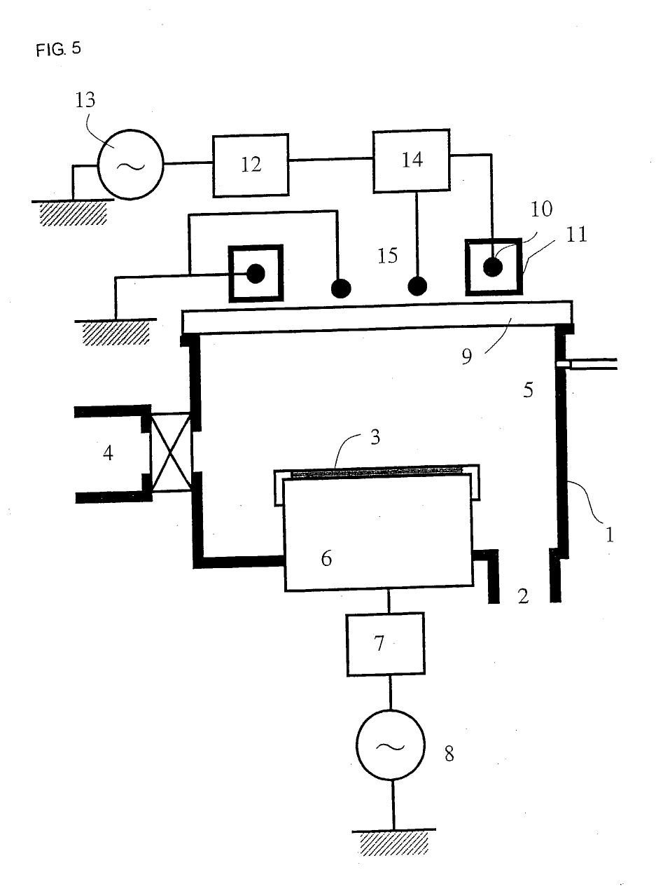

Another embodiment of the invention is shown in FIG. 5. In the embodiment shown in FIG. 5, a usual induction coil 15 corresponding to another plasma source in FIG. 1 is provided near the center of a processing chamber. In recent years, due to an increase in wafer size the plasma uniformity within the processing chamber has become important. In order to control the plasma uniformity, it is effective to provide induction coils of a plurality of systems and to adopt a method by which the current balance of these coils is changed. In the embodiment shown in FIG. 5, a plasma is ignited by use of the induction coil provided in the center and the plasma density is raised to a high level. At the same time, by use of a current flowing through an electric conductor provided near the peripheral portion, a plasma excellent in circumferential uniformity is generated in a large area.

Plasma distribution control is realized by controlling the balance of the current flowing through the induction coil 15 and the electric conductor 11. Because this induction coil 15 provided in the center portion has coil ends, a plasma generated by this coil may become a little eccentric. However, for the generation of a plasma having good axial symmetry, plasma generation in the peripheral portion is much important than plasma generation near the center. Therefore, a plasma having high azimuthal uniformity can be generated when a current is caused to flow to a certain degree through the electric conductor which is provided on the outer side and plasma generation is carried out in the peripheral portion.

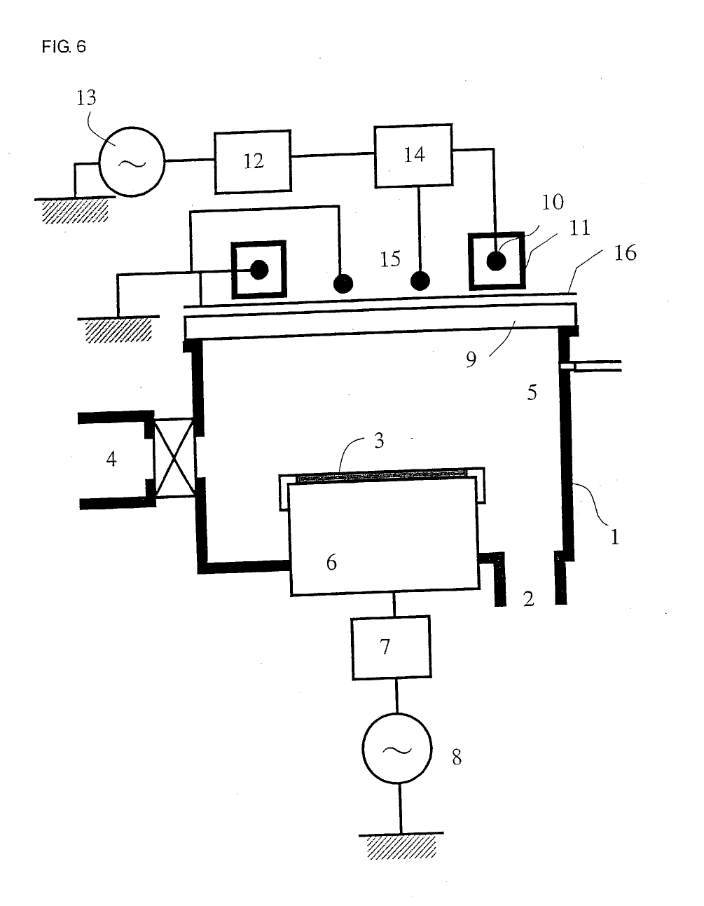

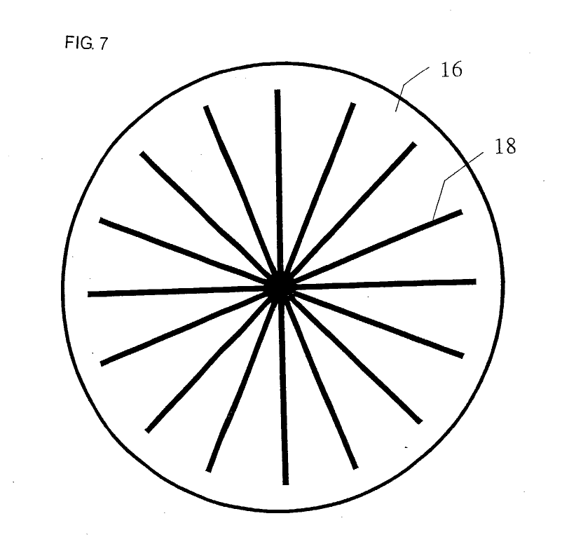

FIG. 6 shows a further embodiment of the invention. In addition to the arrangement of FIG. 5, a Faraday shield 16 which is an electrically conductive material having radial slits 18 as shown in FIG. 7 is provided between a plasma and an induction coil/an electric conductor. The Faraday shield is a shield which cuts off the capacitive coupling between the coil/electric conductor and the plasma. This Faraday shield, which is usually electrically grounded, eliminates the circumferential plasma nonuniformity due to the effect of the coil voltage and prevents the wastage of an insulating material.

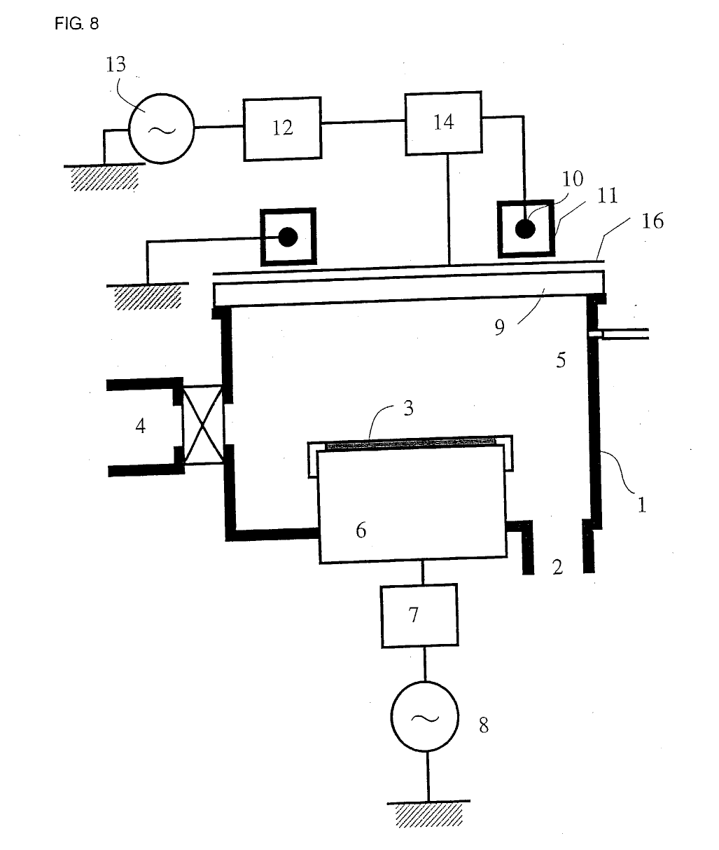

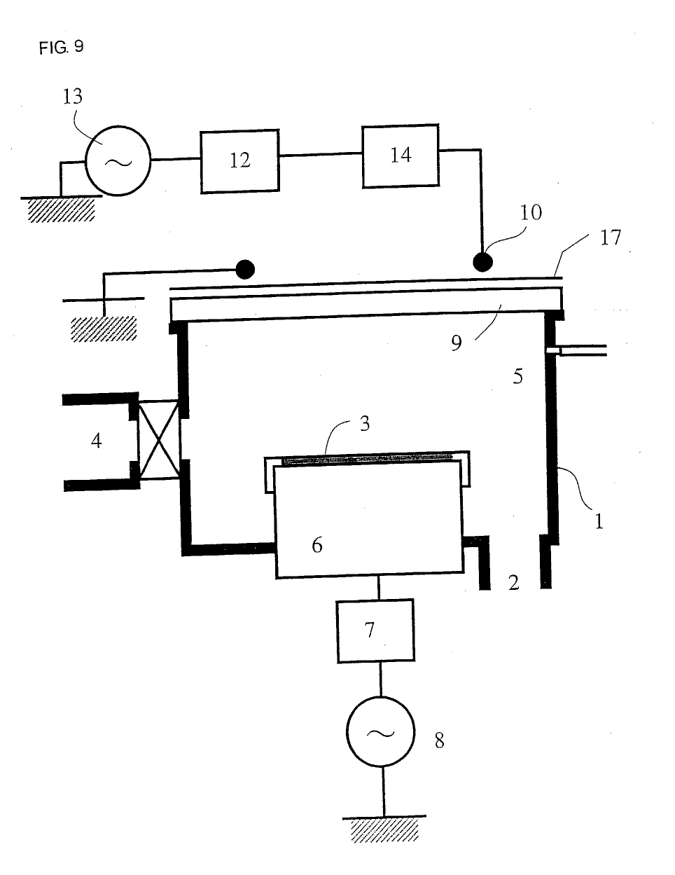

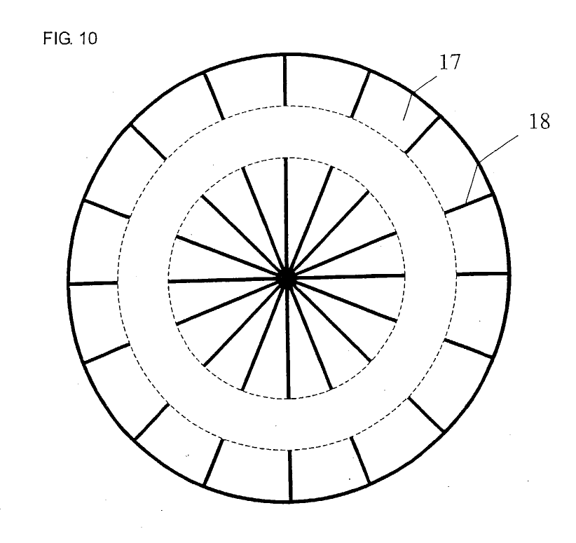

Although a Faraday shield is usually grounded, it is also effective to apply a high-frequency voltage to this part as shown in the embodiment shown in FIG. 8 in order to control the reaction of the surface of an insulating material. At this time, as described above, it is known that in an inductively coupled plasma apparatus, a plasma is generated during ignition and at a low density in a manner of capacitive coupling due to a high-voltage generated in the induction coil. Therefore, by applying a voltage to this shield, it is possible to ignite a plasma. That is, this Faraday shield functions also as another plasma source described in FIG. 1 FIG. 9 shows still another embodiment of the present invention. In FIG. 9, an induced current is caused to flow through an electric conductor 17 which is substantially a flat plate and a plasma is generated by this current. The flat-plate-shaped electric conductor has slits 18 as shown in FIG. 10 and the induced current flows concentrating on a portion connected in ring shape. It is desirable that the slit width be sufficiently small so that an induction field generated by an induction coil has no effect on a plasma (less than 2 mm). The induced current flowing through the ring-shaped portion efficiently generates a plasma.

The embodiments of the invention were described above by taking a plasma etching apparatus for the fabrication of semiconductor devices as an example. However, the invention is not limited to a plasma etching apparatus and can also be applied to a plasma CVD apparatus, a plasma ashing apparatus, a plasma sputtering apparatus, etc. The invention can be applied not only to the processing of semiconductor devices, but also to the processing of liquid crystal display substrates and other surface processing in general.

As described above, according to the plasma processing apparatus of the invention, completely azimuthal plasma uniformity is realized. The plasma etching effect becomes uniform azimuthally and it is necessary only that in establishing plasma etching process conditions, radial uniformity alone is taken into consideration and hence etching conditions can be easily and rapidly determined. As a result, the plasma processing performance as a whole and the working rate of the apparatus improve, permitting fine etching with a high throughput, high-quality film deposition, surface processing, etc.

What is claimed is:

1. A plasma processing apparatus, comprising:
a processing chamber;
means for introducing a processing gas;
evacuation means;
a stage on which a workpiece is placed; and
power supply means to generate a plasma;
wherein at least one induction coil connected to said power supply means generating an induced current in an electrically conductive member in circular shape, in ring shape or in any other shapes which are substantially similar to these shapes, provided so as to be inductively coupled with said coil, and a plasma being generated within the processing chamber by the induced current flowing through said electrically conductive member.

2. The plasma processing apparatus according to claim 1, further comprising another induction coil inductively coupled directly with a plasma.

3. The plasma processing apparatus according to claim 1, further comprising an electric conductor having a slit in a direction transversing said coil disposed at least between the induction coil and a plasma generation space, said electric conductor being capable of electrical grounding.

4. The plasma processing apparatus according to claim 1, further comprising an electric conductor having a slit in a direction transversing said coil disposed at least between the induction coil and a plasma generation space, said electric conductor permitting application of a high frequency voltage.

5. The plasma processing apparatus according to claim 1, further comprising some auxiliary means for plasma generation.
